(19) United States
(12) Patent Application Publication
(10) Pub. No.: US 2008/0123266 A1
(43) Pub. Date: May 29, 2008

(54) DISPLAY DEVICE HAVING A HOUSING WITH AN OPTICAL REFLECTING MIRROR DISPOSED THEREON

(76) Inventor: Chih-Peng Hung, Yilan County (TW)

Correspondence Address: NORTH AMERICA INTELLECTUAL PROPERTY CORPORATION, P.O. BOX 506, MERRIFIELD, VA, 22116, US

(21) Appl. No.: 11/531,686

(22) Filed: Sep. 13, 2006

(30) Foreign Application Priority Data
Jun. 9, 2006 (TW) 095120571

(51) Int. Cl. H05K 5/00

(52) U.S. Cl. 361/681

(57) ABSTRACT

A display device is disclosed. The display device includes a bottom base, a housing, a display unit, and an optical reflecting mirror. The housing is connected to the bottom base in a position-adjustable manner. The display unit is disposed on a first side of the housing for displaying an image signal. The optical reflecting mirror is disposed on a second side of the housing, wherein the first side and the second side are different from each other.

### BACKGROUND OF THE INVENTION

1. Field of the Invention

The present invention relates to a display device, and more particularly, to a display device having a housing with an optical reflecting mirror disposed on one side of the housing.

2. Description of the Prior Art

Many electronic products in the market have display devices for displaying image signals, for example, personal computers (PCs), personal digital assistants (PDAs), liquid crystal display televisions (LCD TVs), or notebook computers. Typically, a display device of the prior art comprises a housing, a bottom base, and a display unit. The display unit can be an LCD panel and is disposed in the housing for displaying image signals. The bottom base is connected to the housing for supporting the housing.

Typically, the display unit is fixedly disposed in the housing, and the housing is fixedly connected to the bottom base. When the bottom base is fixed at a specific location, the relative position of the display unit to the bottom base is thus determined and cannot be modified in the future. Moreover, display devices of the prior art have only the basic function of displaying image signals and thus should be further enhanced or improved.

### SUMMARY OF THE INVENTION

It is therefore one of the objectives of the present invention to provide a display device to solve the above mentioned problems of the prior art. The display device comprises a bottom base; a housing, connected to the bottom base in a position-adjustable manner; a display unit, disposed on a first side of the housing for displaying an image signal; and an optical reflecting mirror, disposed on a second side of the housing, wherein the first side and the second side are different from each other.

The present invention further provides a display device, comprising: a U-shaped bottom base, having a first stand and a second stand, wherein the first stand and the second stand are separated by a preset distance; a housing, pivotedly connected between the first stand and the second stand in a rotatable manner and thus able to selectively rotate between a first position and a second position, wherein a middle position exists between the first position and the second position being apart from the first position and the second position by a same distance substantially; a display unit, disposed on a first side of the housing for selectively displaying a first image signal or a second image signal, wherein the second image signal is an upside down image signal of the first image signal; wherein when the housing is located between the first position and the middle position, the display unit displays the first image signal, and when the housing is located between the middle position and the second position, the display unit displays the second image signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a three-dimensional view of a display device according to a first embodiment of the present invention.

FIG. 2 is a three-dimensional view of the display device in FIG. 1, wherein a housing of the display device has rotated to 180 degrees relative to a bottom base along a direction shown by an arrow.

FIG. 3 is a three-dimensional view of a display device according to a second embodiment of the present invention.

FIG. 4 is a three-dimensional view of the display device in FIG. 3, wherein a housing of the display device has rotated to 180 degrees relative to a bottom base along a direction shown by an arrow.

FIG. 5 is a three-dimensional front view of a display device according to a third embodiment of the present invention.

FIG. 6 is a three-dimensional view of the display device in FIG. 5, wherein a housing of the display device has rotated to a middle position along a direction shown by an arrow.

FIG. 7 is a three-dimensional view of the display device in FIG. 5, wherein a housing of the display device has rotated to a second position along a direction shown by an arrow.

FIG. 8 is a three-dimensional back view of the display device in FIG. 7.

### DETAILED DESCRIPTION

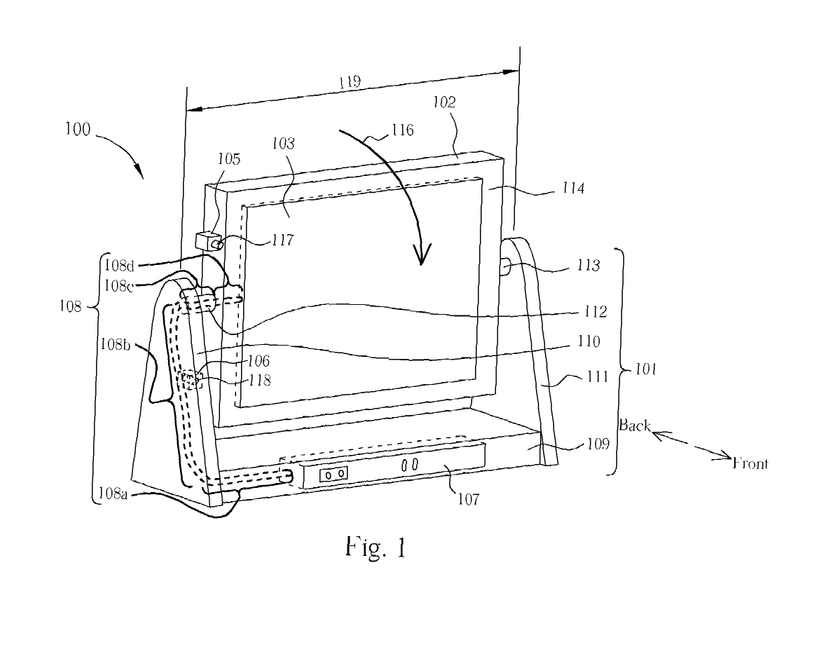

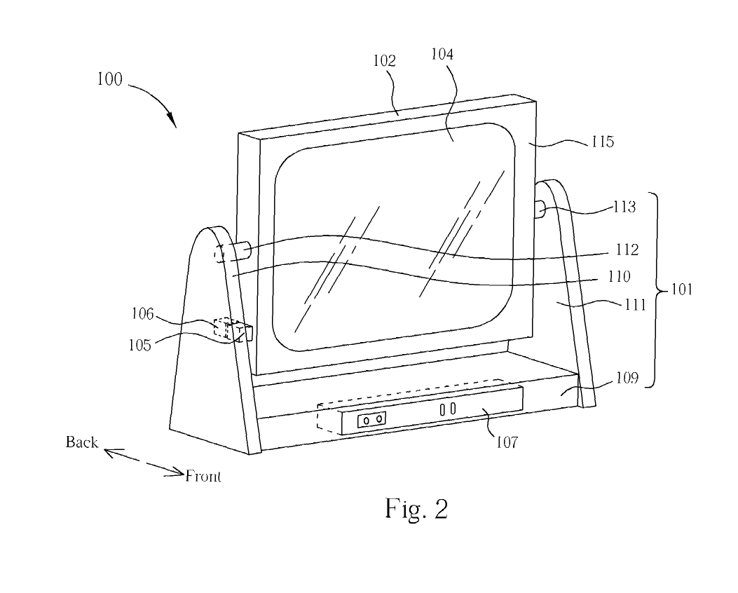

FIG. 1 is a three-dimensional view of a display device 100 according to a first embodiment of the present invention. FIG. 2 is a three-dimensional view of the display device 100 in FIG. 1, wherein a housing 102 of the display device 100 has rotated to 180 degrees relative to a bottom base 101 along a direction shown by an arrow 116.

In this embodiment, the display device 100 comprises a bottom base 101, a housing 102, a display unit 103, an optical reflecting mirror 104, a first stopper 105, a second stopper 106, an input/output unit 107, and an electrical transmission cord 108.

The bottom base 101 comprises a base body 109, a first stand 110, a second stand 111, a first pivoting component 112, and a second pivoting component 113. The first stand 110 and the second stand 111 are fixedly connected to the base body 109 in a corresponding manner. Moreover, the first stand 110 and the second stand 111 are separated by a preset distance 119 and extend upwards respectively. The first pivoting component 112 is fixedly connected between the first stand 110 and the housing 102, and the second pivoting component 113 is fixedly connected between the second stand 111 and the housing 102, thereby the housing 102 is able to pivot on the first stand 110 and the second stand 111 in a rotatable manner. Furthermore, the housing 102 can rotate up to 180 degrees relative to the bottom base 101.

The display unit 103 is fixedly disposed on a first side 114 of the housing 102 for displaying an image signal. In this embodiment, the display unit 103 is a liquid crystal display (LCD) panel. Moreover, the optical reflecting mirror 104 is fixedly disposed on a second side 115 of the housing 102. The first side 114 and the second side 115 are different from each other. Moreover, the first side 114 is virtually parallel with the second side 115.

The first stopper 105 is fixedly disposed at the housing 102, and the second stopper 106 is fixedly disposed at the first stand 110 of the bottom base 101. Therefore, when the housing 102 rotates to 180 degrees relative to the bottom base 101 along a direction shown by an arrow 116, a protruding portion 117 of the first stopper 105 is engaged with a dented portion 118 of the second stopper 106 to stop the housing 102 from rotating over 180 degrees, as shown in FIG. 2. As mentioned above, the display unit 103 is fixedly disposed on the first side 114 of the housing 102, and the optical reflecting mirror 104 is fixedly disposed on the second side 115 of the housing 102, so the display unit 103 and the optical reflecting mirror 104 will accompany the housing 102 to rotate relative to the bottom base 101.

The input/output unit 107 is disposed in the base body 109 and electrically connected to the display unit 103 by the electrical transmission cord 108 for transmitting the image signal or other control signals. The electrical transmission cord 108 is formed by connecting a plurality of line segments 108a, 108b, 108c, and 108d sequentially, the line segments 108a, 108b, 108c, and 108d being disposed in the base body 109, the first stand 110, the first pivoting component 112, and the housing 102 respectively. Therefore, when the housing 102 rotates to 180 degrees relative to the bottom base 101, the electrical transmission cord 108 will not get stuck or entwined.

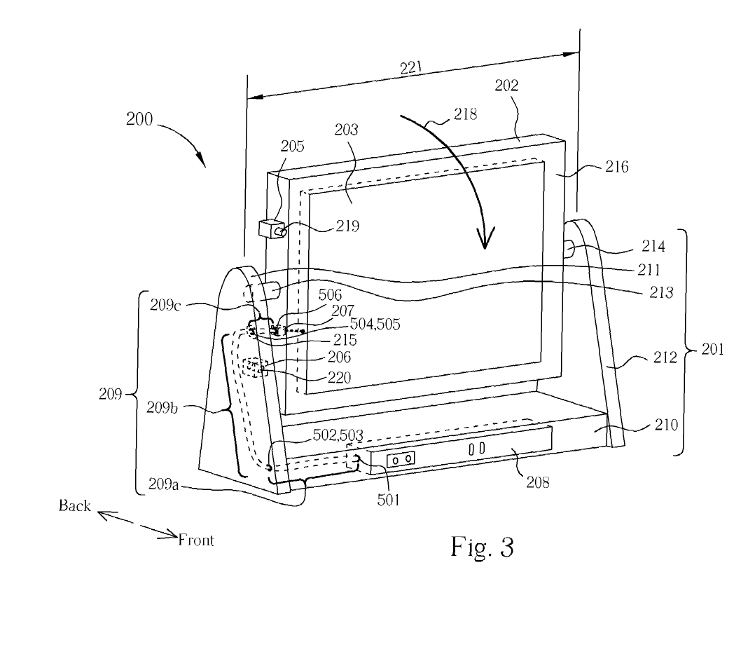

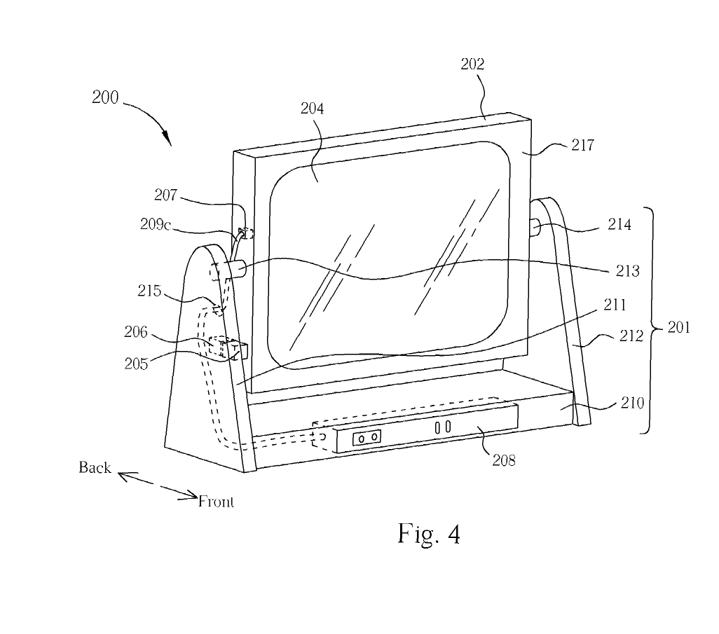

FIG. 3 is a three-dimensional view of a display device 200 according to a second embodiment of the present invention. FIG. 4 is a three-dimensional view of the display device 200 in FIG. 3, wherein a housing 202 of the display device 200 has rotated to 180 degrees relative to a bottom base 201 along a direction shown by an arrow 218.

In this embodiment, the display device 200 comprises a bottom base 201, a housing 202, a display unit 203, an optical reflecting mirror 204, a first stopper 205, a second stopper 206, a first input/output unit 207, a second input/output unit 208, and an electrical transmission cord 209.

The bottom base 201 comprises a base body 210, a first stand 211, a second stand 212, a first pivoting component 213, and a second pivoting component 214. The first stand 211 and the second stand 212 are fixedly connected to the base body 210 in a corresponding manner. Moreover, the first stand 211 and the second stand 212 are separated by a preset distance 221 and extend upwards respectively. The first stand 211 comprises an opening 215 adjacent to the first pivoting component 213. The first pivoting component 213 is fixedly connected between the first stand 211 and the housing 202, and the second pivoting component 214 is fixedly connected between the second stand 212 and the housing 202, thereby the housing 202 is able to pivot on the first stand 211 and the second stand 212 in a rotating fashion. Furthermore, the housing 202 can rotate up to 180 degrees relative to the bottom base 201.

The display unit 203 is fixedly disposed on a first side 216 of the housing 202 for displaying an image signal. In this embodiment, the display unit 203 is an LCD panel. Moreover, the optical reflecting mirror 204 is fixedly disposed on a second side 217 of the housing 202. The first side 216 and the second side 217 are different from each other. Moreover, the first side 216 is virtually parallel with the second side 217.

The first stopper 205 is fixedly disposed at the housing 202, and the second stopper 206 is fixedly disposed at the first stand 211 of the bottom base 201. Therefore, when the housing 202 rotates to 180 degrees relative to the bottom base 201 along a direction shown by an arrow 218, a protruding portion 219 of the first stopper 205 is engaged with a dented portion 220 of the second stopper 206 to stop the housing 202 from rotating over 180 degrees, as shown in FIG. 4. As mentioned above, the display unit 203 is fixedly disposed on the first side 216 of the housing 202, and the optical reflecting mirror 204 is fixedly disposed on the second side 217 of the housing 202, so the display unit 203 and the optical reflecting mirror 204 will accompany the housing 202 to rotate relative to the bottom base 201.

The first input/output unit 207 is disposed in the housing 202 and electrically connected to the display unit 203 for transmitting the image signal or other control signals. The first input/output unit 207 is adjacent to the first pivoting component 213. The second input/output unit 208 is disposed in the base body 210 and electrically connected to the first input/output unit 207 by the electrical transmission cord 209 for transmitting the image signal or other control signals.

The electrical transmission cord 209 comprises a first line segment 209a, a second line segment 209b, and a third line segment 209c. The first line segment 209a has a first end point 501 and a second end point 502. The first end point 501 is connected to the second input/output unit 208. The first line segment 209a is disposed in the base body 210. The second line segment 209b has a third end point 503 and a fourth end point 504. The third end point 503 is connected to the second end point 502. The second line segment 509b is virtually disposed in the first stand 211. The fourth end point 504 passes through the opening 215 and thus is exposed outside the first stand 211. The third line segment 209c has a fifth end point 505 and a sixth end point 506. The fifth end point 505 is connected to the fourth end point 504. The sixth end point 506 is connected to the first input/output unit 207. The third line segment 209c is exposed outside the housing 202. In this embodiment, the exposed part of the electrical transmission cord 209, mainly the third line segment 209c, is relatively short and very close to the first pivoting component 213 where the housing 202 is connected to the bottom base 201. Therefore, when the housing 202 rotates to 180 degrees relative to the bottom base 201, the electrical transmission cord 209 will not get stuck or entwined.

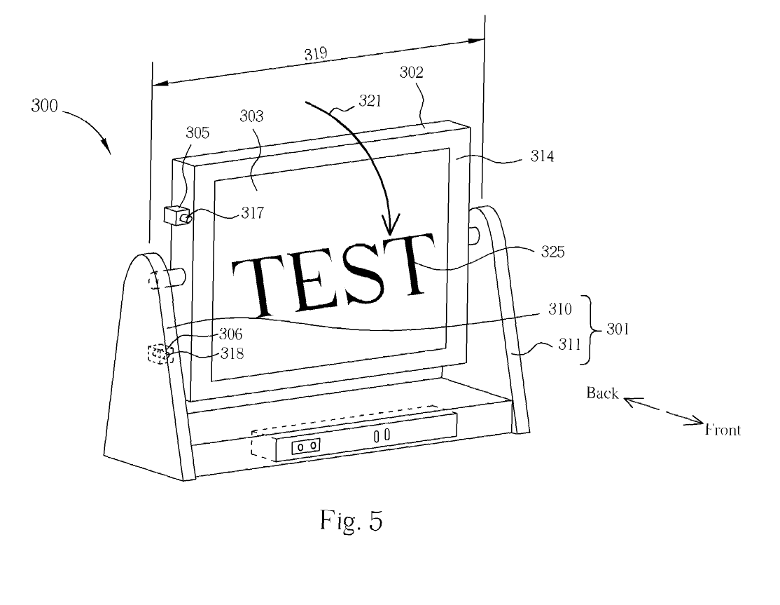

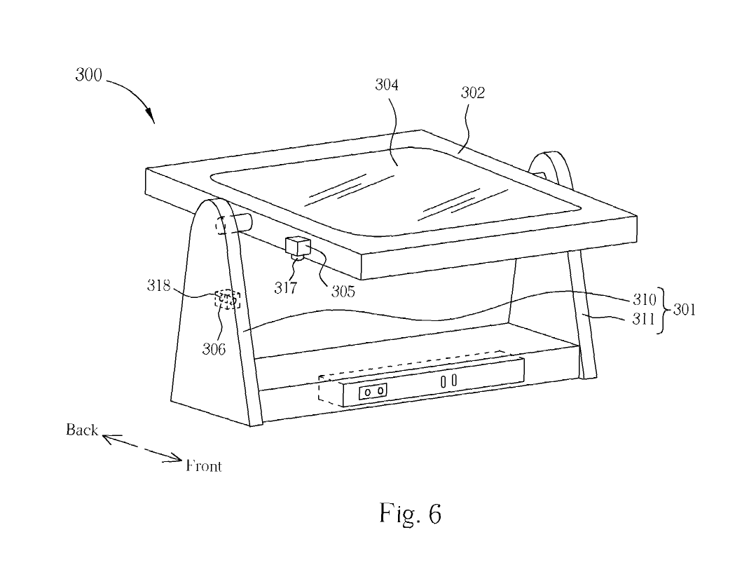

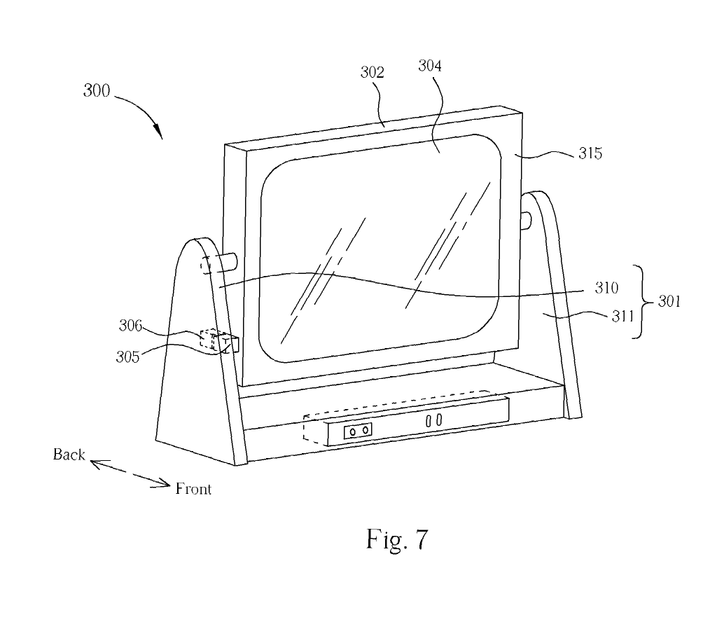

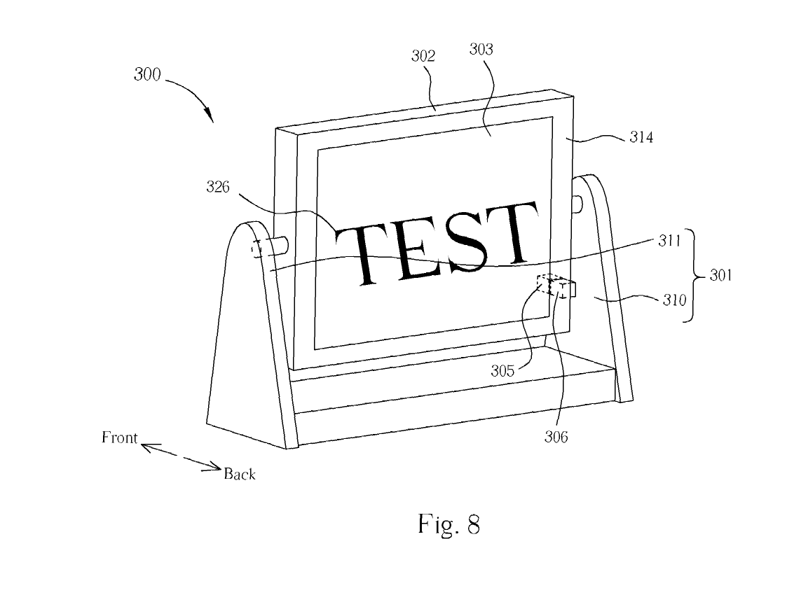

FIG. 5 is a three-dimensional front view of a display device 300 according to a third embodiment of the present invention, wherein a housing 302 of the display device 300 is located at a first position. FIG. 6 is a three-dimensional view of the display device 300 in FIG. 5, wherein a housing 302 of the display device 300 has rotated to a middle position along a direction shown by an arrow 321. FIG. 7 is a three-dimensional view of the display device 300 in FIG. 5, wherein a housing 302 of the display device 300 has rotated to a second position along a direction shown by an arrow 321. FIG. 8 is a three-dimensional back view of the display device 300 in FIG. 7.

In this embodiment, the display device 300 comprises a U-shaped bottom base 301, a housing 302, a display unit 303, an optical reflecting mirror 304, a first stopper 305, and a second stopper 306.

The U-shaped bottom base 301 comprises a first stand 310 and a second stand 311. The first stand 310 and the second stand 311 are separated by a preset distance 319. The housing 302 is pivotedly connected between the first stand 310 and the second stand 311 in a rotatable manner. Further, the housing 302 can rotate substantially 360 degrees relative to the U-shaped bottom base 301.

The display unit 303 is fixedly disposed on a first side 314 of the housing 302 for selectively displaying a first image signal 325 or a second image signal 326. In this embodiment, the display unit 303 is an LCD panel. Moreover, the optical reflecting mirror 304 is fixedly disposed on a second side 315 of the housing 302. The first side 314 and the second side 315 are different from each other. Moreover, the first side 314 is virtually parallel with the second side 315. Further, the first stopper 305 is fixedly disposed at the housing 302, and the second stopper 306 is fixedly disposed at the first stand 310 of the U-shaped bottom base 301.

The housing 302 selectively rotates between a first position and a second position. The housing 302 in FIG. 5 is located at the first position, while the housing 302 in FIG. 7 is located at the second position. Moreover, there exists a middle position between the first position and the second position. The housing 302 in FIG. 6 is located at the middle position. As shown in drawings, the middle position is apart from the first position and the second position by the same distance substantially.

When the housing 302 is located between the first position and the middle position, i.e. during the process when the housing 302 is rotated from the first position to the middle position along a direction shown by an arrow 321, the display unit 303 displays the first image signal 325. Please refer to FIG. 5. The housing 302 in FIG. 5 is located at the first position, so the display unit 303 displays the first image signal 325, i.e. “TEST” as shown. Moreover, when the housing 302 is located between the middle position and the second position, i.e. during the process when the housing 302 is rotated from the middle position to the second position along a direction shown by the arrow 321, the display device 300 turns the first image signal 325 upside down to form the second image signal 326 for displaying on the display unit 303. Please refer to FIG. 8. The housing 302 in FIG. 8 is located at the second position, so the display unit 303 displays the second image signal 326, i.e. “TEST” as shown.

Moreover, when the housing 302 is located at the first position as shown in FIG. 5, the first stopper 305 is independent of the second stopper 306. When the housing 302 rotates to the second position relative to the U-shaped bottom base 301 along a direction shown by the arrow 321 as shown in FIG. 7, a protruding portion 317 of the first stopper 305 is engaged with a dented portion 318 of the second stopper 306 to hold the housing 302 at the second position.

As described in the above three embodiments, the housing of the display device of the present invention can rotate up to 180 degrees along a preset direction, for example, a direction shown by the arrow in FIG. 1, 3, or 5. When used as a normal display, the display device utilizes the display unit (such as an LCD panel) facing a user for displaying the image signal, so the user can view the image signal. Moreover, the display device has the optical reflecting mirror on the opposite side from the side the display unit is located. Therefore, when the housing rotates to 180 degrees relative to the bottom base along a direction shown by the arrow in FIG. 1, 3, or 5, the display unit and the optical reflecting mirror will accompany the housing to rotate to 180 degrees relative to the bottom base. The optical reflecting mirror is thus rotated to face the user, so the display device can be used as a mirror. Compared with the display device of the prior art, the display device of the present invention not only has the basic function of displaying image signals, but also an additional function as a mirror.

Moreover, in an embodiment of a display device of the present invention, an input/output unit is disposed in a base body of a bottom base and electrically connected to a display unit by an electrical transmission cord, such as an audio-video (AV) signal line or a power line. The electrical transmission cord is disposed in the bottom base and a housing. Therefore, when the housing rotates relative to the bottom base, the electrical transmission cord will not get stuck or entwined.

Moreover, in another embodiment of a display device of the present invention, an input/output unit is disposed in a base body of a bottom base, and another input/output unit is disposed in a housing. The two input/output units are electrically connected by an electrical transmission cord, such as an AV signal line or a power line. Moreover, one stand of the bottom base has an opening adjacent to where the housing is connected to the bottom base. Most of the electrical transmission cord is disposed in the bottom base, while a small part of the electrical transmission cord passes through the opening and thus is exposed outside the bottom base. The exposed part of the electrical transmission cord is further connected to the input/output unit in the housing. Therefore, when the housing rotates relative to the bottom base, the electrical transmission cord will not get stuck or entwined.

Moreover, in another embodiment of a display device of the present invention, when a housing of the display device rotates to 180 degrees relative to a bottom base along a direction shown by the arrow in FIG. 1, 3, or 5, an optical reflecting mirror disposed on the display device is rotated to face a user, and the display device will turn the currently shown image signal upside down to form a new image signal for displaying on a display unit of the display device. Therefore, the turned display unit can still display the new image signal correctly. In such a way, the user can use the display device as a mirror and a display at the same time.

Moreover, an embodiment of a display device of the present invention comprises a pair of stoppers that can be engaged with each other. The two stoppers are fixedly disposed at a housing and a bottom base respectively. Therefore, when the housing rotates to 180 degrees relative to the bottom base, the two stoppers are engaged with each other to hold the housing at its current position, thus stopping the housing from rotating over 180 degrees along a direction shown by the arrow in FIG. 1, 3, or 5. Furthermore, a display unit and an optical reflecting mirror both disposed on the housing can be firm and free of vibrations when the stoppers are used.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A display device, comprising:
a bottom base;
a housing, connected to the bottom base in a position-adjustable manner;
a display unit, disposed on a first side of the housing for displaying an image signal; and
an optical reflecting mirror, disposed on a second side of the housing, wherein the first side and the second side are different from each other.

2. The display device of claim 1, further comprising an input/output unit, disposed in the housing and electrically connected to the display unit for transmitting the image signal, wherein the input/output unit is adjacent to where the housing is connected to the bottom base.

3. The display device of claim 1, wherein the first side is virtually parallel with the second side.

4. The display device of claim 1, wherein the housing can rotate up to 180 degrees relative to the bottom base, the display unit is fixedly disposed on the first side of the housing, and the optical reflecting mirror is fixedly disposed on the second side of the housing, thereby the display unit and the optical reflecting mirror are able to accompany the housing to rotate up to 180 degrees relative to the bottom base.

5. The display device of claim 4, further comprising:
a first stopper, fixedly disposed at the housing; and
a second stopper, fixedly disposed at the bottom base;
wherein when the housing rotates to 180 degrees relative to the bottom base, the second stopper contacts with the first stopper to stop the housing from rotating over 180 degrees.

6. The display device of claim 5, wherein when the housing rotates to 180 degrees relative to the bottom base, the second stopper is engaged with the first stopper to stop the housing from rotating over 180 degrees.

7. The display device of claim 1, wherein the bottom base comprises:
a base body;
a first stand and a second stand, fixedly connected to the base body in a corresponding manner, wherein the first stand and the second stand are separated by a preset distance and extend upwards respectively; and
a first pivoting component and a second pivoting component, wherein the first pivoting component is fixedly connected between the first stand and the housing, and the second pivoting component is fixedly connected between the second stand and the housing, thereby the housing is able to pivot on the first stand and the second stand in a rotating fashion.

8. The display device of claim 7, further comprising an input/output unit, disposed in the base body and electrically connected to the display unit for transmitting the image signal.

9. The display device of claim 8, further comprising an electrical transmission cord, connected between the input/output unit and the display unit for transmitting the image signal.

10. The display device of claim 9, wherein the electrical transmission cord is formed by connecting a plurality of line segments sequentially, and the line segments are disposed in the base body, the first stand, the first pivoting component, and the housing respectively.

11. The display device of claim 7, further comprising:
a first input/output unit, disposed in the housing and electrically connected to the display unit for transmitting the image signal, wherein the first input/output unit is adjacent to the first pivoting component; and
a second input/output unit, disposed in the base body and electrically connected to the first input/output unit for transmitting the image signal.

12. The display device of claim 11, further comprising an electrical transmission cord, connected between the first input/output unit and the second input/output unit for transmitting the image signal.

13. The display device of claim 12, wherein the first stand comprises an opening adjacent to the first pivoting component, and the electrical transmission cord comprises:
a first line segment, having a first end point and a second end point, wherein the first end point is connected to the second input/output unit, and the first line segment is disposed in the base body;
a second line segment, having a third end point and a fourth end point, wherein the third end point is connected to the second end point, the second line segment is virtually disposed in the first stand, and the fourth end point passes through the opening and thus is exposed outside the first stand; and
a third line segment, having a fifth end point and a sixth end point, wherein the fifth end point is connected to the fourth end point, the sixth end point is connected to the first input/output unit, and the third line segment is exposed outside the housing.

14. A display device, comprising:
a U-shaped bottom base, having a first stand and a second stand, wherein the first stand and the second stand are separated by a preset distance;
a housing, pivotedly connected between the first stand and the second stand in a rotatable manner and thus selectively rotating between a first position and a second position, wherein a middle position exists between the first position and the second position being apart from the first position and the second position by a same distance substantially;
a display unit, disposed on a first side of the housing for selectively displaying a first image signal or a second image signal, wherein the second image signal is an upside down image signal of the first image signal;
wherein when the housing is located between the first position and the middle position, the display unit displays the first image signal, and when the housing is located between the middle position and the second position, the display unit displays the second image signal.

15. The display device of claim 14, further comprising an optical reflecting mirror, disposed on a second side of the housing, wherein the first side and the second side are different from each other.

16. The display device of claim 14, wherein the first side is virtually parallel with the second side.

17. The display device of claim 14, wherein the housing can rotate substantially 360 degrees relative to the U-shaped bottom base.

18. The display device of claim 14, further comprising:
a first stopper, fixedly disposed at the housing; and
a second stopper, fixedly disposed at the U-shaped bottom base;
wherein when the housing is located at the first position, the first stopper is independent of the second stopper, and when the housing is located ate the second position, the second stopper is engaged with the first stopper to hold the housing at the second position.
